(19) United States
(12) Patent Application Publication
(10) Pub. No.: US 2026/0271462 A1
(43) Pub. Date: Sep. 10, 2026

(54) Elastomeric Impact Protection Mask for LED Display

(71) Applicant: Global Product Sources, LLC, Madison, TN (US)

(72) Inventor: Jeremy D. Lee, Madison, TN (US)

(73) Assignee: Global Product Sources, LLC, Madison, TN (US)

(21) Appl. No.: 19/550,685

(22) Filed: Feb. 26, 2026

Related U.S. Application Data
(60) Provisional application No. 63/769,294, filed on Mar. 10, 2025.

(51) Int. Cl. H10H 29/852; A63B 71/06

(52) U.S. Cl. CPC H10H 29/852; A63B 71/0622

(57) ABSTRACT

A protective mask protects an LED display panel from damage due to object impacts. The mask includes a rear surface that covers the LED display panel, and a front surface opposing the rear surface. The mask includes multiple apertures extending through the protective mask, wherein each aperture receives a corresponding one of multiple LED modules extending from the front of the LED display panel. The mask includes multiple outwardly extending protective enclosures, each continuously surrounding a corresponding one of the apertures. Each protective enclosure includes first and second side walls, a lower wall, and an upper wall. The second side wall is on the opposite side of the aperture from the first side wall. The lower wall is between the first and second side walls. The upper wall is between the first and second side walls, and is on the opposite side of the aperture from the lower side wall.

### FIELD OF THE INVENTION

This invention relates to LED display panels used in stadiums and arenas for sporting events for advertising and informational purposes, and to structures for protecting LED display panels from impact damage. More particularly, this invention relates to elastomeric mask structures that cover LED display panels used in sporting event venues to protect from damage caused by objects impacting the front surfaces of the panels.

### BACKGROUND OF THE INVENTION

Large light emitting diode (LED) displays are used in stadiums and arenas for sporting events for advertising and informational purposes. Due to their size and placement, such displays are vulnerable to impact from baseballs, soccer balls, hockey pucks, etc., which can cause considerable damage to the LED devices on the surface of the display panels. Attempts have been made in the past to ruggedize such displays by adding raised protective ridges on the display panels between the rows of LED devices. An example of such a prior system is the MA960-S Stadium Perimeter LED Display manufactured by Shenzhen Unit LED Co., Ltd., that includes a mask overlaying the LED array.

Some prior masks included small individual flexible shaders that overhang each LED module in the array. Those prior shaders were disposed directly above the LED module to block the sun. In some prior mask systems, the shaders were rubberized to allow for impact from foreign objects. Over time the single shader extending over the LED becomes brittle and breaks. This shader approach to LED protection has been generally abandoned, and in the last few years, separate nets have been installed in front of such LED arrays to protect them from impacts.

Embodiments of the invention described herein solve the prior problems by providing a rubberized system that completely surrounds each LED module in the array. The system includes a plastic base layer that goes around all sides of the LED module, and the base layer is over-molded with a rubberized top layer. This solution eliminates the need for a net, and allows the LED display to receive an impact directly without damaging the LED modules.

### SUMMARY OF THE INVENTION

The above and other needs are met by a protective mask for protecting an LED display panel from damage due to object impacts. The protective mask includes a rear surface configured to contact and substantially cover the LED display panel, and a front surface disposed opposite the rear surface. The spacing between the front and rear surfaces defines the thickness of the protective mask. The mask includes multiple apertures that extend through the protective mask, with each aperture being aligned with and configured to receive a corresponding one of the LED modules extending from the front surface of the LED display panel. The mask also includes a plurality of protective enclosures extending outward from its front surface. Each protective enclosure continuously surrounds a corresponding one of the apertures. Each protective enclosure includes a first side wall, a second side wall, a lower wall, and an upper wall. The first side wall has a first side wall height defined by the distance from the rear surface of the mask to the front edge of the first side wall. The second side wall, which is disposed on the opposite side of the aperture from the first side wall, has a second side wall height defined by the distance from the rear surface of the mask to the front edge of the second side wall. The lower wall, which is disposed between the first and second side walls, has a lower wall height defined by the distance from the rear surface of the mask to the front edge of the lower wall. The upper wall is disposed between the first and second side walls, and is on the opposite side of the aperture from the lower side wall. The upper wall has an upper wall height defined by the distance from the rear surface of the mask to the front edge of the upper wall.

In some embodiments, the upper wall height is greater than the first side wall height, greater than the second side wall height, and greater than the lower wall height. In these embodiments, the upper wall forms an awning that shades enclosed the LED module from direct overhead sun exposure.

In some embodiments, the first sidewall height, second sidewall height, and lower wall height are equal, and the upper wall height ranges from about 1.5 to 1.6 times the height of the other walls.

In some embodiments, the upper wall height is 5.5 mm, the lower wall height is 3.5 mm, the first side wall height is 3.5 mm, and the second side wall height is 3.5 mm.

In some embodiments, the first side wall of each enclosure has two opposing outer edges that define the first side wall width, the second side wall of each enclosure has two opposing outer edges that define the second side wall width, the lower wall of each enclosure has two opposing outer edges that define the lower wall width, and the upper wall of each enclosure has two opposing outer edges that define the upper wall width. One of the outer edges of the first side wall is connected to one of the outer edges of the lower wall, and the other of the outer edges of the first side wall is connected to one of the outer edges of the upper wall. One of the outer edges of the second side wall is connected to one of the outer edges of the lower wall, and the other of the outer edges of the second side wall is connected to one of the outer edges of the upper wall. In this manner, the connections of the outer edges of the first side wall to the upper wall, the upper wall to the second side wall, the second side wall to the lower wall, and the lower wall to the first side wall form the protective enclosure that continuously surrounds the corresponding one of the apertures.

In some embodiments, each LED module is viewable over a horizontal viewing angle of greater than 120 degrees, as determined by the first side wall height and the second side wall height. In some embodiments, the horizontal viewing angle is 126 degrees.

In some embodiments, each LED module is viewable over a vertical viewing angle of greater than 90 degrees, as determined by the upper wall height and the lower wall height. In some embodiments, the vertical viewing angle is 92 degrees.

In some embodiments, the front surface of the protective mask that is immediately adjacent each aperture is defined by a series of ridges disposed in parallel to the first and second side walls of the protective enclosure surrounding the aperture.

In some embodiments, the rear surface comprises a base layer formed by injection molding, and the front surface and the protective enclosures comprise an over-mold layer that covers the base layer.

In some embodiments, the base layer comprises a thermoplastic material, and the over-mold layer comprises an elastomeric material.

In some embodiments, the base layer comprises polycarbonate plastic, and the over-mold layer comprises thermoplastic rubber (TPR), thermoplastic polyurethane (TPU), or ethylene propylene diene monomer (EPDM).

In some embodiments, the plurality of apertures comprise 384 apertures disposed in a 24 by 16 rectangular array.

In some embodiments, each aperture in the plurality of apertures comprises a 3.5 mm by 3.5 mm square aperture.

In some embodiments, the horizontal and vertical spacing of the plurality of apertures ranges from 1.9 mm to 16 mm.

In some embodiments, the horizontal and vertical spacing of the plurality of apertures is 10.4 mm.

In some embodiments, the first sidewalls of the enclosures are spaced apart from the second sidewalls of adjacent enclosures.

In some embodiments, the upper walls of the enclosures are spaced apart from the lower walls of adjacent enclosures.

In some embodiments, the base layer of the mask includes a plurality of protrusions extending outward therefrom, and the upper walls of the enclosures are over-molded onto the protrusions.

### BRIEF DESCRIPTION OF THE DRAWINGS

Other embodiments of the invention will become apparent by reference to the detailed description in conjunction with the figures, wherein elements are not to scale so as to more clearly show the details, wherein like reference numbers indicate like elements throughout the several views, and wherein:

FIG. 1 depicts a top front perspective view of a protective mask for an LED display screen according to an embodiment of the invention;

FIG. 2 depicts a front elevation view and bottom edge view of the protective mask shown in FIG. 1;

FIG. 3 depicts a rear elevation view of the protective mask shown in FIG. 1;

FIG. 4 depicts a vertical cross-section view of the protective mask shown in FIG. 1;

FIG. 5 depicts an end view of the protective mask shown in FIG. 1;

FIG. 6 depicts a bottom front perspective view of the protective mask shown in FIG. 1 installed on an LED display panel, with a detail view of an upper corner of the mask;

FIGS. 7-10 depict detailed views of portions of the protective mask shown in FIG. 1 installed on an LED display panel;

FIG. 11 depicts a horizontal cross-section view of the protective mask shown in FIG. 1 installed on an LED display panel; and

FIG. 12 depicts a vertical cross-section view of the protective mask shown in FIG. 1 installed on an LED display panel.

### DETAILED DESCRIPTION OF THE INVENTION

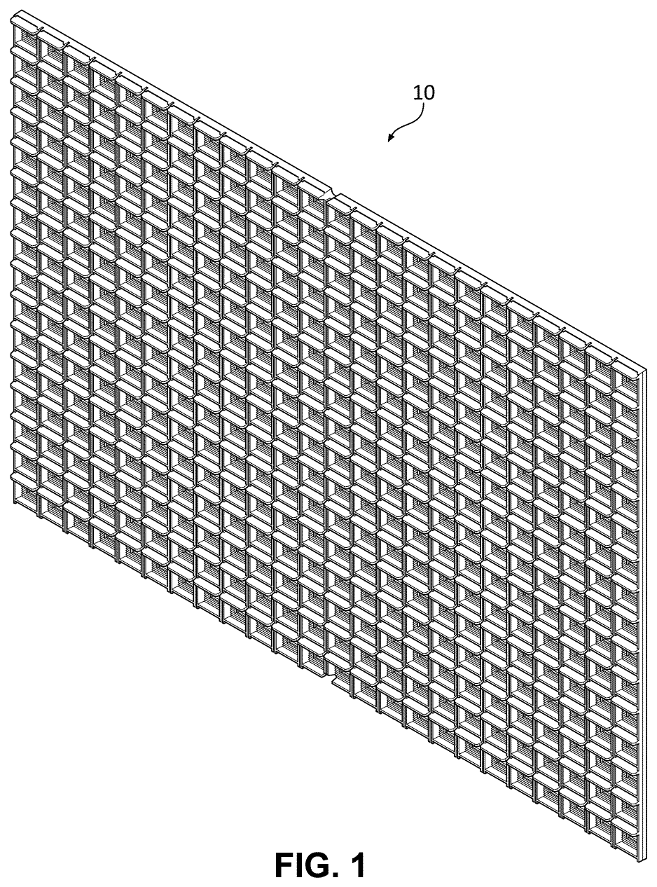

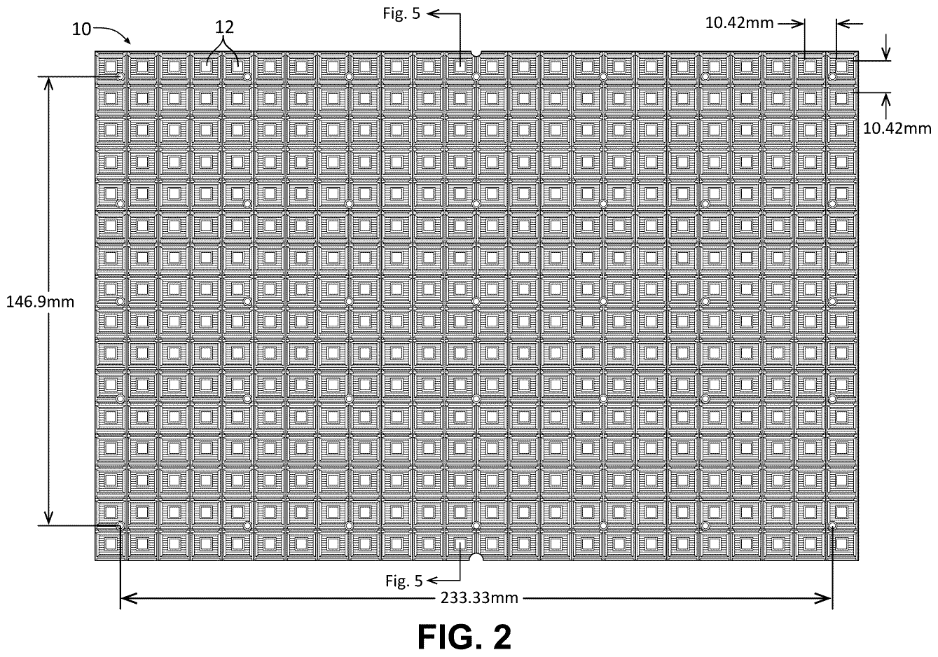

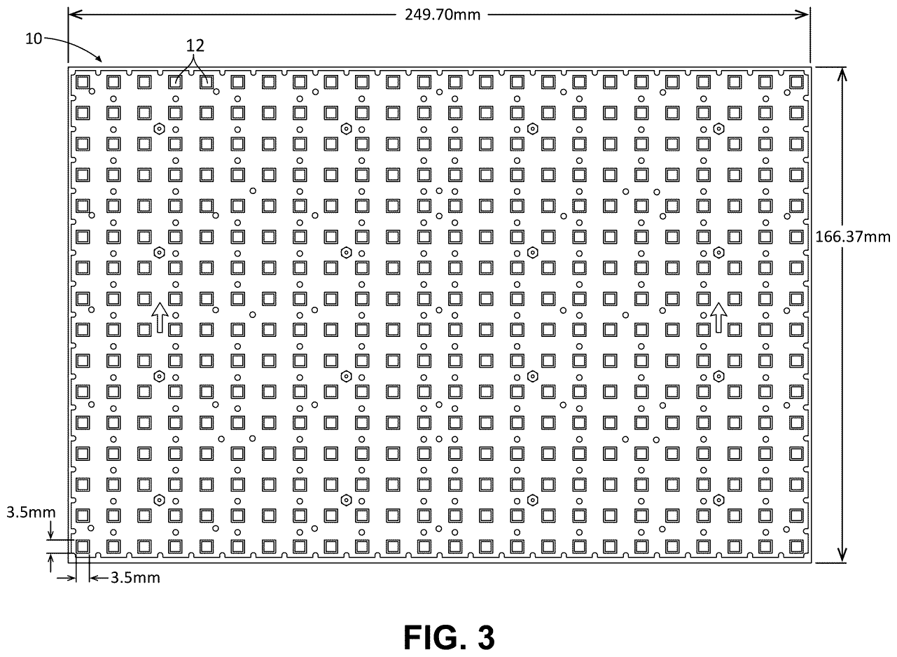

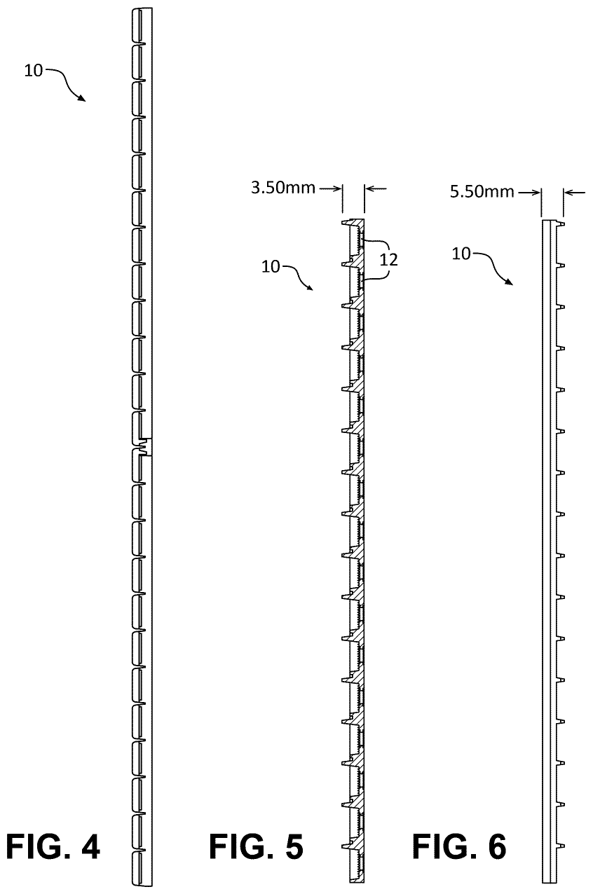

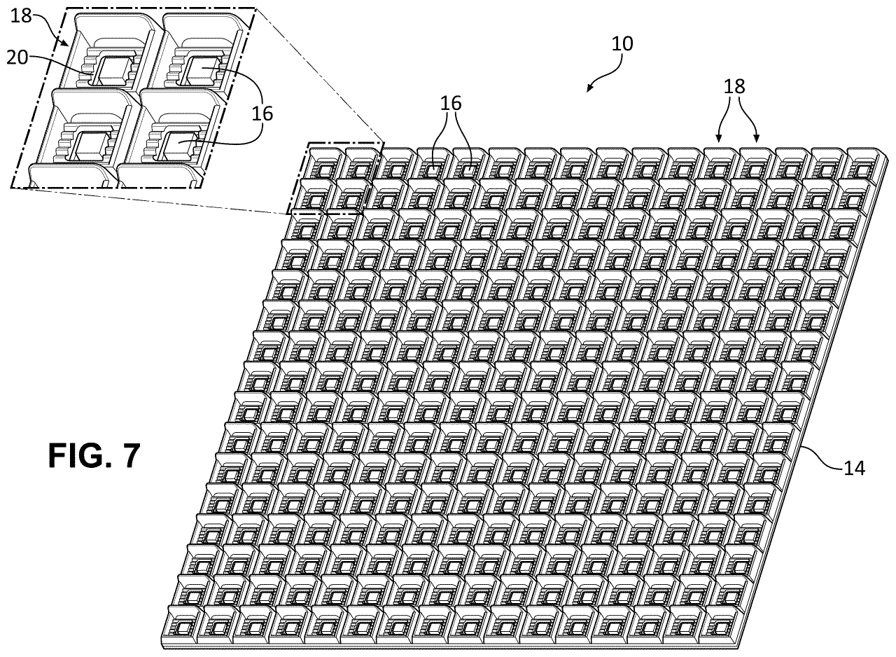

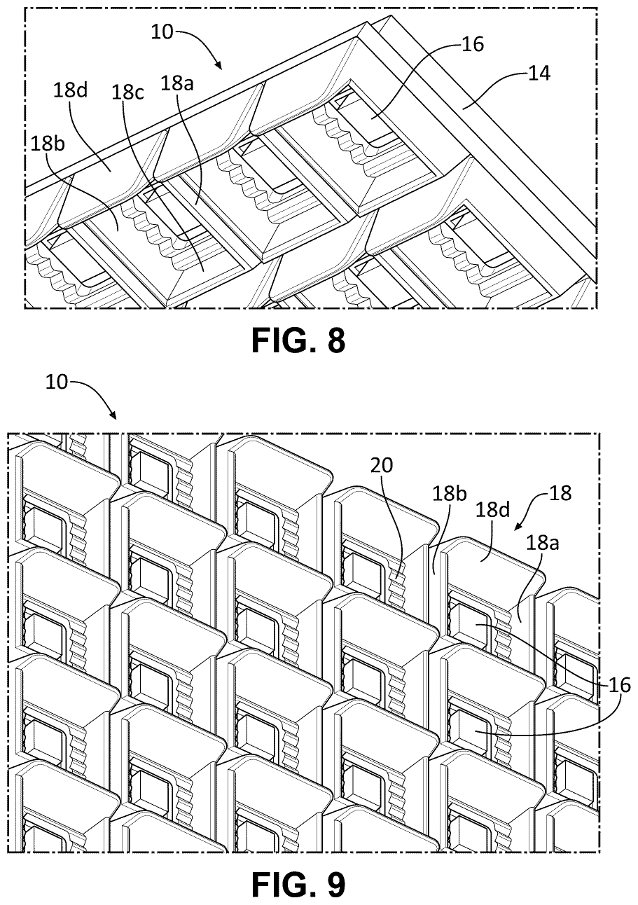

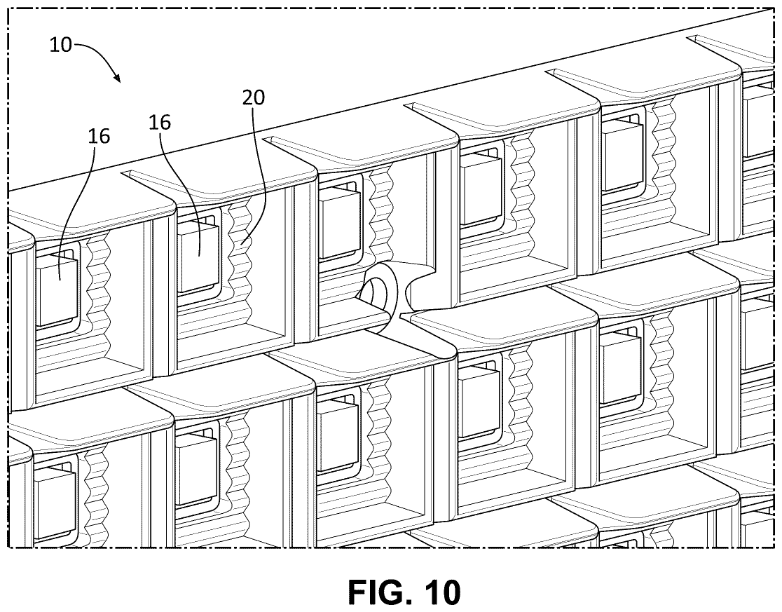

As shown in FIGS. 1-12, embodiments described herein are directed to a protective mask 10 for installation on an LED display panel 14. In the embodiment depicted in FIG. 1, the mask 10 includes a 24×16 array of apertures 12 (total of 384 apertures). Each aperture 12, which is preferably a 3.5 mm by 3.5 mm square, receives an LED module 16 attached to the LED display panel 14. It will be appreciated that the apertures 12 and the LED modules 16 may have other shapes in other embodiments, such as circular.

In the embodiments described herein, the LED modules 16 are vertically and horizontally spaced at a pitch of about 10.4 mm. In other embodiments, the vertical and horizontal pitches may range from about 1.9 mm to 16 mm.

Surrounding each of the apertures 12 in the mask 10 is a protective enclosure 18 extending outward from the front surface of the mask 10. Each enclosure 18 includes a first side wall 18a, a second side wall 18b, a lower wall 18c, and an upper wall 18d. In a preferred embodiment, the walls 18a-18d are joined together at their edges to form a continuous enclosure 18 that surrounds the corresponding LED module 16. The upper wall 18d preferably extends further outward than the other walls 18a-18c, thereby forming an awning that shades the LED module 16 from direct overhead sun exposure. This shading provides a higher visual contrast ratio. In a preferred embodiment, the distance from the rear surface of the mask 10 to the front edge of the upper wall 18d is 5.5 mm, and the distance from the rear surface of the mask to the front edges of the first side wall 18a, the second side wall 18b, and the lower wall 18c is 3.5 mm. The distance from the rear surface of the mask 10 to the front edges of the walls 18a-18d is also referred to herein as the “height” of the walls.

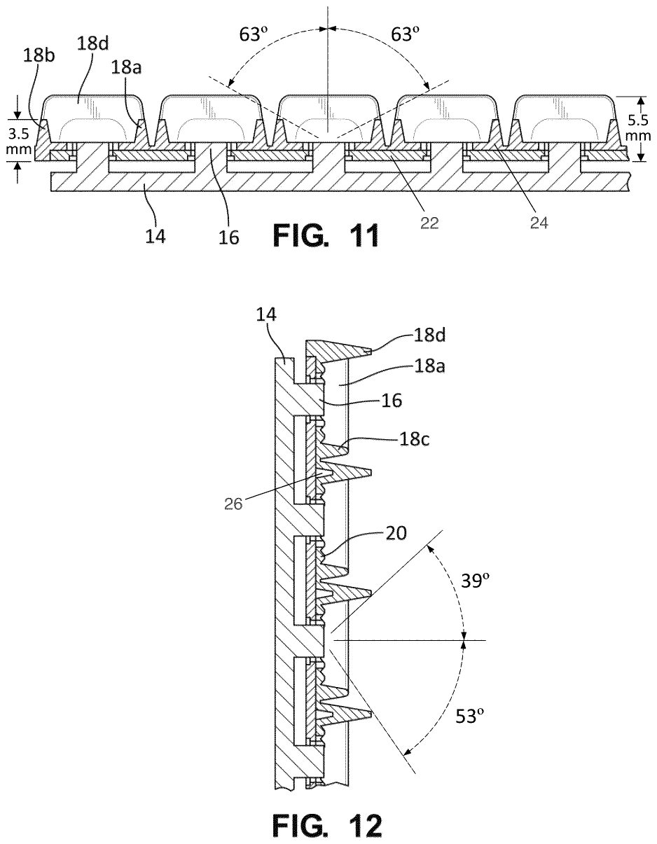

As shown in FIGS. 11 and 12, light emitted from each LED module 16 can be seen over a horizontal viewing angle of about 126 degrees, and over a vertical viewing angle of about 92 degrees.

The front surface 20 of the mask 10 that surrounds the apertures 12 within the walls of each enclosure 18 is preferably corrugated, wherein the ridges and valleys of the corrugations are disposed in parallel to the upper and lower walls 18d and 18c. These corrugations increase the strength and rigidity of the mask 10.

In a preferred embodiment depicted in FIGS. 11 and 12, the mask 10 comprises an injection-molded base layer 22 and an over-molded elastomeric layer 24 that covers the base layer 22. The base layer 22 preferably comprises polycarbonate plastic. The over-mold layer 24 preferably comprises an elastomeric material, such as a thermoplastic elastomer (TPE) rubber with a UV stabilizer as an anti-aging additive. In other embodiments, the elastomeric layer 24 may comprise thermoplastic rubber (TPR), thermoplastic polyurethane (TPU), or ethylene propylene diene monomer (EPDM). The resulting flexibility of the walls 18a-18d of each enclosure 18 provides a distinct advantage in impact absorption compared to prior art structures formed from more rigid materials.

Also in a preferred embodiment, the base layer 22 includes outwardly extending molded protrusions 26 as shown in FIG. 12. The portions of the elastomeric layer 26 that form the upper walls 18d of the enclosures 18 are over-molded onto the protrusions 26. The protrusions 26 provide additional surface area to enhance the structural support for the upper walls 18d that, because they extend further outward from the other walls 18a, 18b, and 18c, tend to absorb a larger share of impact forces to which the mask 10 is exposed.

The foregoing description of preferred embodiments for this invention have been presented for purposes of illustration and description. They are not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A protective mask for protecting a light emitting diode (LED) display panel from damage due to object impacts, wherein the LED display panel includes a plurality of LED modules extending from a front surface of the LED display panel, the protective mask comprising:
a rear surface configured to contact and substantially cover the front surface of the LED display panel;
a front surface disposed opposite the rear surface, wherein a spacing between the front surface and the rear surface defines a thickness of the protective mask;
a plurality of apertures arranged in a grid pattern, each aperture comprising an opening from the front surface to the rear surface, wherein each aperture is aligned with and configured to receive a corresponding one of the LED modules on the LED display panel; and
a plurality of protective enclosures extending outward from the front surface of the protective mask, each protective enclosure continuously surrounding a corresponding one of the apertures, each protective enclosure comprising:
a first side wall having a first side wall height defined by a distance from the rear surface of the mask to a front edge of the first side wall;
a second side wall disposed on an opposite side of the aperture from the first side wall, the second side wall having a second side wall height defined by a distance from the rear surface of the mask to a front edge of the second side wall;
a lower wall disposed between the first and second side walls, the lower wall having a lower wall height defined by a distance from the rear surface of the mask to a front edge of the lower wall; and
an upper wall disposed between the first and second side walls, and on an opposite side of the aperture from the lower side wall, the upper wall having an upper wall height defined by a distance from the rear surface of the mask to a front edge of the upper wall.

2. The protective mask of claim 1 wherein the upper wall height is greater than the first side wall height, the upper wall height is greater than the second side wall height, and the upper wall height is greater than the lower wall height, whereby the upper wall forms an awning that shades an LED module disposed in enclosed aperture from direct overhead sun exposure.

3. The mask of claim 1 wherein the first side wall height, second side wall height, and lower wall height are equal, and the upper wall height ranges from about 1.5 to 1.6 times the first side wall height, second side wall height, and lower wall height.

4. The protective mask of claim 1 wherein the upper wall height is 5.5 mm, the lower wall height is 3.5 mm, the first side wall height is 3.5 mm, and the second side wall height is 3.5 mm.

5. The protective mask of claim 1 wherein:
the first side wall of each enclosure has two opposing outer edges that define a first side wall width, the second side wall of each enclosure has two opposing outer edges that define a second side wall width, the lower wall of each enclosure has two opposing outer edges that define a lower wall width, and the upper wall of each enclosure has two opposing outer edges that define an upper wall width,
one of the outer edges of the first side wall is connected to one of the outer edges of the lower wall, and the other of the outer edges of the first side wall is connected to one of the outer edges of the upper wall, and
one of the outer edges of the second side wall is connected to one of the outer edges of the lower wall, and the other of the outer edges of the second side wall is connected to one of the outer edges of the upper wall,
such that the connections of the outer edges of the first side wall to the upper wall, the upper wall to the second side wall, the second side wall to the lower wall, and the lower wall to the first side wall form the protective enclosure that continuously surrounds the corresponding one of the apertures.

6. The protective mask of claim 1 wherein, as determined by the first side wall height and the second side wall height, each LED module is viewable over a horizontal viewing angle of greater than 120 degrees.

7. The protective mask of claim 6 wherein, as determined by the first side wall height and the second side wall height, each LED module is viewable over a horizontal viewing angle of 126 degrees.

8. The protective mask of claim 1 wherein, as determined by the upper wall height and the lower wall height, each LED module is viewable over a vertical viewing angle of greater than 90 degrees.

9. The protective mask of claim 8 wherein, as determined by the upper wall height and the lower wall height, each LED module is viewable over a vertical viewing angle of 92 degrees.

10. The protective mask of claim 1 wherein the front surface of the protective mask immediately adjacent each aperture is defined by a series of ridges disposed in parallel to the first and second side walls of the protective enclosure surrounding the aperture, wherein the series of ridges are configured to increase strength and rigidity of the protective mask.

11. The protective mask of claim 1 wherein:
the rear surface comprises a base layer formed by injection molding; and
the front surface and the protective enclosures comprise an over-mold layer that covers the base layer.

12. The protective mask of claim 11 wherein the base layer comprises a thermoplastic material, and the over-mold layer comprises an elastomeric material.

13. The protective mask of claim 11 wherein the base layer comprises polycarbonate plastic.

14. The protective mask of claim 11 wherein the over-mold layer comprises one or more of thermoplastic rubber (TPR), thermoplastic polyurethane (TPU), and ethylene propylene diene monomer (EPDM).

15. The mask of claim 11 wherein the plurality of protective enclosures are formed as part of the over-mold layer.

16. The mask of claim 1 wherein the first sidewalls of the plurality of enclosures are spaced apart from the second sidewalls of adjacent enclosures.

17. The mask of claim 1 wherein the upper walls of the plurality of enclosures are spaced apart from the lower walls of adjacent enclosures.

18. The mask of claim 1, wherein the front surface comprises a plurality of protrusions extending outward therefrom, and wherein the upper walls of the plurality of enclosures are over-molded onto the plurality of protrusions.

19. The protective mask of claim 1 wherein the plurality of apertures comprise 384 apertures disposed in a 24 by 16 rectangular array.

20. An elastomeric protective mask for protecting a light emitting diode (LED) display panel from damage due to object impacts, wherein the LED display panel includes a plurality of LED modules extending from a front surface of the LED display panel, the elastomeric protective mask comprising:
a rear surface configured to contact and substantially cover the front surface of the LED display panel, the rear surface comprising a base layer of thermoplastic material formed by injection molding;
a front surface disposed opposite the rear surface, wherein a spacing between the front surface and the rear surface defines a thickness of the protective mask, the front surface comprising an elastomeric material over-molded onto the base layer;
a plurality of apertures extending through the elastomeric protective mask, each aperture aligned with and configured to receive a corresponding one of the plurality of LED modules;
a plurality of protective enclosures extending outward from the front surface of the elastomeric protective mask, each protective enclosure comprising a portion of the over-mold layer that covers the base layer, each protective enclosure continuously surrounding a corresponding one of the apertures, each protective enclosure comprising:
a first side wall having a first side wall height defined by a distance from the rear surface of the mask to a front edge of the first side wall;
a second side wall disposed on an opposite side of the aperture from the first side wall, the second side wall having a second side wall height defined by a distance from the rear surface of the mask to a front edge of the second side wall;
a lower wall disposed between the first and second side walls, the lower wall having a lower wall height defined by a distance from the rear surface of the mask to a front edge of the lower wall; and
an upper wall disposed between the first and second side walls, and on an opposite side of the aperture from the lower side wall, the upper wall having an upper wall height defined by a distance from the rear surface of the mask to a front edge of the upper wall,
wherein the upper wall height is greater than the first side wall height, the upper wall height is greater than the second side wall height, and the upper wall height is greater than the lower wall height, whereby the upper wall forms an awning that shades an LED module disposed in enclosed aperture from direct overhead sun exposure,
wherein, as determined by the first side wall height and the second side wall height, each LED module is viewable over a horizontal viewing angle of greater than 120 degrees, and
wherein, as determined by the upper wall height and the lower wall height, each LED module is viewable over a vertical viewing angle of greater than 90 degrees.
